(19) United States
(12) Patent Application Publication
(10) Pub. No.: US 2026/0196258 A1
(43) Pub. Date: Jul. 9, 2026

(54) TWO-DIMENSIONAL FERROMAGNETIC THIN FILM, METHOD OF MANUFACTURING THE SAME, AND RACETRACK MEMORY COMPRISING THE SAME

(71) Applicant: INDUSTRY-ACADEMIC COOPERATION FOUNDATION, YONSEI UNIVERSITY, Seoul (KR)

(72) Inventors: Mann Ho CHO, Seoul (KR); Seung Won RHO, Seoul (KR)

(21) Appl. No.: 19/437,737

(22) Filed: Dec. 31, 2025

(30) Foreign Application Priority Data
Jan. 3, 2025 (KR) 10-2025-0001028
Dec. 29, 2025 (KR) 10-2025-0211794

(51) Int. Cl. G11C 11/16

(52) U.S. Cl. CPC G11C 11/1675; G11C 11/161

(57) ABSTRACT

An embodiment relates to a two-dimensional ferromagnetic thin film manufactured through an effective method of controlling real-space Berry curvature using bulk DMI in a two-dimensional ferromagnetic material to overcome the limitation of real-space Berry curvature limited to two dimensions caused by interface DMI, and represented by the chemical formula M_{1+δ}X₂ (M is a transition metal, X is a chalcogen element, 0<δ<1), wherein the two-dimensional ferromagnetic thin film includes a structure in which MX₂ atomic layers are stacked, and M atoms are self-inserted between the MX₂ atomic layers to control the δ value of M_{1+δ}X₂, so that real-space Berry curvature can be formed inside the two-dimensional ferromagnetic thin film.

### CROSS REFERENCE TO RELATED APPLICATION

The present application claims priority to Korean Patent Application 10-2025-0001028, filed Jan. 3, 2025, and Korean Patent Application 10-2025-0211794, filed Dec. 29, 2025, in the Korean Intellectual Property Office, the entire contents of which are incorporated here for all purposes by this reference.

### BACKGROUND

The present invention relates to spintronics applications, and more particularly, to a two-dimensional ferromagnetic thin film in which real-space Berry curvature is controlled by controlling the amount of self-insertion at the atomic level in a two-dimensional ferromagnetic material, a method for manufacturing the same, and a racetrack memory including the same.

Spintronics leverages the spin degree of freedom of electrons to overcome the limitations of existing charge-electron-based devices and implement new functionalities, it is attracting attention in the development of next-generation memory and logic devices with low power consumption and high speed. Typical spintronics applications include non-volatile memory devices such as magnetoresistive random access memory (MRRAM).

Currently, next-generation memories like MRRAM are entering the commercialization phase due to their high integration and durability, and racetrack memory is also being extensively studied.

Among these, chiral spin structures with real-space Berry curvature, similar to magnetic skyrmions, are being studied as a key technology for the development of racetrack memory, and the field of study that studies these chiral spin structures is called chiral spintronics.

The real-space Berry curvature arising from chiral spin structures is a key concept in chiral spintronics research, and in thin films, it can be detected through the topological Hall effect during Hall measurements. Real-space Berry curvature is induced by asymmetric spin arrangements, which act like a virtual magnetic field on electron transport, influencing conduction.

The Dzyaloshinskii-Moriya interaction (DMI) plays a crucial role in inducing these chiral spin structures, occurring in systems with broken inversion symmetry and strong spin-orbit interactions.

To date, the interfacial DMI effect has primarily been utilized to generate chiral spin structures (e.g., Co/Pt junction structures); however, interfacial DMI confines chiral spin structures to two-dimensional planes, limiting their use in high-density chiral spin devices.

Therefore, research is needed to develop technologies that can efficiently generate and control chiral spin structures in the three-dimensional space by controlling the crystal structure symmetry within the material (bulk) rather than at the interface, thereby inducing bulk DMI.

### RELATED ART DOCUMENT

### Patent Document

Republic of Korea Patent No. 10-2759050

### SUMMARY

The technical problem to be achieved by the present invention is to solve the problems of the above-mentioned prior art, and to provide a two-dimensional ferromagnetic thin film manufactured through an effective method of controlling real-space Berry curvature using bulk DMI in a two-dimensional ferromagnetic material in order to overcome the limitation of real-space Berry curvature limited to two dimensions caused by interface DMI, a method of manufacturing the same, and a racetrack memory including the same.

The aspect of the disclosure is not limited to that mentioned above, and other aspects not mentioned will be clearly understood by those skilled in the art from the description below.

An embodiment of the disclosure provides a two-dimensional ferromagnetic thin film.

In an embodiment of the disclosure, the two-dimensional ferromagnetic thin film includes a structure in which MX₂ atomic layers are stacked, and
a real-space Berry curvature is formed inside the two-dimensional ferromagnetic thin film by inserting M atoms between the MX₂ atomic layers to control the δ value of M_{1+δ}X₂.

In addition, the X is tellurium (Te) or selenium (Se), and the M is chromium (Cr), manganese (Mn), vanadium (V), or iron (Fe).

In addition, in an embodiment of the disclosure, the M is chromium (Cr),
the X is tellurium (Te), and the two-dimensional ferromagnetic thin film is Cr_{1+δ}Te₂ (0<δ<1).

In addition, in an embodiment of the disclosure, the value δ, which is the amount of the self-inserted M atoms, is 0.25≤δ≤0.6.

In addition, in an embodiment of the disclosure, the value δ, which is the amount of the self-inserted M atoms, is 0.25≤δ≤0.35 or 0.5≤δ≤0.6.

In addition, in an embodiment of the disclosure, the two-dimensional ferromagnetic thin film includes a skyrmion, which is a chiral spin structure formed inside the thin film with the real-space Berry curvature.

An embodiment of the disclosure provides a method for manufacturing a two-dimensional ferromagnetic thin film.

In an embodiment of the disclosure, the method may include: preparing a substrate; and co-depositing a transition metal and a chalcogen element on the substrate to form an MX₂ atomic layer, and self-inserting the transition metal between the MX₂ atomic layers to manufacture a two-dimensional ferromagnetic thin film represented by the chemical formula M_{1+δ}X₂ (M is a transition metal, X is a chalcogen element, 0<δ<1).

In addition, in an embodiment of the disclosure, the transition metal is chromium (Cr), and the chalcogen element (X) is tellurium (Te).

In addition, in an embodiment of the disclosure, the value δ, which is the amount of the self-inserted M atoms, is 0.25≤δ≤0.35 or 0.5<δ≤0.6.

In addition, in an embodiment of the disclosure, in the manufacturing of the two-dimensional ferromagnetic thin film, the element ratio of the transition metal and chalcogen elements co-deposited on the substrate is 1:2.71 to 1:6.03, and the temperature of the substrate is maintained in the range of 200° C. to 360° C. to control the δ value, which is the amount of self-inserted M atoms.

In addition, in an embodiment of the disclosure, the method may further include, after the manufacturing of the two-dimensional ferromagnetic thin film, performing post-heat treatment at a temperature in the range of 200° C. to 360° C. to improve the crystallinity of the two-dimensional ferromagnetic thin film.

An embodiment of the disclosure provides a racetrack memory includes a two-dimensional ferromagnetic thin film.

A two-dimensional ferromagnetic thin film according to an embodiment of the present invention can efficiently control real-space Berry curvature by precisely controlling the amount of self-insertion at the atomic level in a two-dimensional ferromagnetic material, thereby maximizing the phase Hall effect proportional to the real-space Berry curvature, thereby enabling the implementation of a high-performance spintronic device, enabling simpler and more effective real-space Berry curvature control than the existing interface DMI-based method, and providing an effect applicable to next-generation non-volatile memory devices (e.g., racetrack memory) and high-density memory devices.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows the composition and crystal structure of Cr_{1+δ}Te₂ according to the amount of Cr self-insertion;

FIG. 2 is a schematic view of (a) the bulk DMI and (b) the interface DMI, which are physical factors that generate real-space Berry curvature;

FIG. 3 shows a method for measuring the phase Hall effect, which is proportional to real-space Berry curvature, wherein (a) an optical image of a standard Hall bar element for measuring the phase Hall effect, and (b) a graph for separating the phase Hall effect contribution from the Hall effect of a magnetic thin film;

FIGS. 4A-4G show the results of Hall effect measurements of Cr_{1.6}Te₂, including FIG. 4A temperature-dependent Hall resistivity vs. magnetic field graphs (below 50 K), FIG. 4B temperature-dependent anomalous Hall effect extracted from the graph in FIG. 4A, FIG. 4C temperature-dependent phase Hall effect extracted from FIG. 4A, FIG. 4D temperature-dependent Hall resistivity vs. magnetic field graphs (above 50 K), FIG. 4E temperature-dependent anomalous Hall effect amplitude extracted from FIG. 4B and FIG. 4D, FIG. 4F temperature-dependent coercivity extracted from FIG. 4B and FIG. 4D, and FIG. 4G temperature-dependent phase Hall effect amplitude extracted from FIG. 4A;

FIGS. 5A-5C show temperature-dependent Hall resistivity vs. magnetic field graphs of FIG. 5A Cr_{1.5}Te₂, FIG. 5B Cr_{1.35}Te₂, and FIG. 5C Cr_{1.25}Te₂; and

FIG. 6 is a graph that summarizes the phase Hall effect amplitude at 20 K according to the amount of Cr atomic self-insertion, and is a graph that expresses the crystal symmetry for each composition.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part is said to “include” a component, this does not mean that it excludes other components, unless otherwise specifically stated, but rather that it may include other components.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings. For reference, the drawings may be somewhat exaggerated to explain the features of the present invention. In this case, it is preferable to interpret in light of the entire purpose of this specification.

### A Two-Dimensional Ferromagnetic Thin Film According to an Embodiment of the Present Invention is Described.

A two-dimensional ferromagnetic thin film according to an embodiment of the present invention relates to a two-dimensional ferromagnetic thin film represented by the chemical formula M_{1+δ}X₂ (M is a transition metal, X is a chalcogen element, 0<δ<1), wherein the two-dimensional ferromagnetic thin film includes a structure in which MX₂ atomic layers are stacked, and M atoms are self-inserted between the MX₂ atomic layers to control the δ value of M_{1+δ}X₂, so that real-space Berry curvature can be formed inside the two-dimensional ferromagnetic thin film.

Specifically, the two-dimensional ferromagnetic thin film essentially includes a layered structure in which MX₂ atomic layers are vertically stacked by van der Waals forces.

A key feature of the present invention is the self-insertion of excess M atoms into the van der Waals gap between the MX₂ atomic layers.

By precisely controlling the δ value, the amount of self-inserted M atoms, the crystal structural symmetry of the two-dimensional ferromagnetic thin film may be controlled.

This change in symmetry, particularly the destruction of inversion symmetry, induces bulk Dzyaloshinskii-Moriya interaction (Bulk DMI) within the thin film, resulting in the formation of real-space Berry curvature, which acts as an effective magnetic field within the two-dimensional ferromagnetic thin film.

Here, preferably, the X may be a chalcogen element such as tellurium (Te) or selenium (Se), and the M may be a ferromagnetic transition metal such as chromium (Cr), manganese (Mn), vanadium (V), or iron (Fe). These combinations provide strong spin-orbit coupling, allowing the formation of a chiral spin structure.

Here, more preferably, the M is chromium (Cr), X is tellurium (Te), and the two-dimensional ferromagnetic thin film may be Cr_{1+δ}Te₂ (where 0<δ<1).

Here, Cr_{1+δ}Te₂ may maintain ferromagnetism even near room temperature, and the changes in physical properties due to the control of the self-insertion amount can be most pronounced.

At this time, the δ value, which is the amount of the self-inserted M atoms, may be in the range of 0.25≤δ≤0.6.

This is because, if the above δ value is outside the above-mentioned range, the amount of self-inserted Cr atoms is insufficient to break the symmetry of the crystal structure, or conversely, due to excessive insertion of Cr atoms, the crystal structure may transition to a completely different phase, such as a monoclinic system with symmetry, and a problem may occur in which the phase Hall effect and chiral spin structure aimed at in the present invention are not expressed.

Accordingly, the δ value, which is the amount of the self-inserted M atoms, may be 0.25≤δ≤0.6, and more specifically and preferably, the δ value may be in the range of 0.25≤δ≤0.35 or 0.5<δ≤0.6.

At this time, if the δ value exceeds the desired range, the arrangement of the self-inserted Cr atoms may change, forming a structure with crystallographic spatial inversion symmetry.

For example, in the range where the δ value exceeds 0.35 and is less than 0.5, the arrangement order of the Cr self-inserted atoms may deteriorate, or a trigonal structure with a partially different arrangement may form, thereby restoring the spatial inversion symmetry of the crystal structure.

In this case, the symmetry of the crystal structure may cause the bulk DMI to disappear, resulting in the absence of real-space Berry curvature and the observable phase Hall effect.

On the other hand, within the aforementioned preferred range, the crystal structure maintains an asymmetric trigonal structure, enabling strong bulk DMI and phase Hall effects.

Meanwhile, the two-dimensional ferromagnetic thin film may include a chiral spin structure, specifically a skyrmion, formed within the bulk of the thin film due to the real-space Berry curvature.

Here, the skyrmion may refer to a chiral spin structure with particle-like properties formed by a spiral arrangement of spins within a magnetic material.

Specifically, a skyrmion is a structure protected by topological properties, and may exhibit high stability, making it resistant to external local deformation or defects.

Such skyrmions may be formed by the competition between ferromagnetic exchange interactions within the magnetic material and the Zalosinski-Moriya interactions resulting from an asymmetric crystal structure.

In particular, the skyrmion is formed by bulk DMI induced by the crystal structural asymmetry within the film (bulk), not at the interface, and may induce the phase Hall effect, accompanied by real-space Berry curvature, an effective magnetic field generated by electron flow.

Such skyrmions, due to their topological protection, may exhibit particle-like properties that are highly stable against external disturbances.

Therefore, the two-dimensional ferromagnetic thin film may be applied to racetrack memory, a next-generation memory device that uses the movement of skyrmions as a means of information transmission, and may offer the advantages of high density and low power operation.

Below, a method for manufacturing a two-dimensional ferromagnetic thin film that achieves the aforementioned effects will be described.

### A Method for Manufacturing a Two-Dimensional Ferromagnetic Thin Film According to an Embodiment of the Present Invention is Described.

The method for manufacturing a two-dimensional ferromagnetic thin film according to the present invention may be applied to all aspects of the two-dimensional ferromagnetic thin film described above. While detailed descriptions of overlapping elements have been omitted, the same principles apply even if such descriptions are omitted.

The method for manufacturing a two-dimensional ferromagnetic thin film according to an embodiment of the present invention includes: preparing a substrate; co-depositing a transition metal and a chalcogen element on the substrate to form an MX₂ atomic layer; and self-inserting the transition metal between the MX₂ atomic layers to form a two-dimensional ferromagnetic thin film represented by the chemical formula M_{1+δ}X₂ (M is a transition metal, X is a chalcogen element, 0<δ<1).

At this time, the substrate is not limited as long as it is chemically stable, suitable for high-temperature processes, and capable of epitaxial growth of a transition metal chalcogenide compound. For example, the substrate may be a sapphire substrate.

Meanwhile, the transition metal may be chromium (Cr), and the chalcogen element (X) may be tellurium (Te).

Furthermore, in the manufacturing of the two-dimensional ferromagnetic thin film, the element ratio of the transition metal and chalcogen element co-deposited on the substrate is precisely controlled to be in the range of 1:2.71 to 1:6.03, and the substrate temperature is maintained in the range of 200° C. to 360° C., thereby controlling the δ value, which is the amount of self-inserted M atoms.

At this time, the final controlled self-inserted δ value may be in the range of 0.25≤δ≤0.35 or 0.5<δ≤0.6.

At this time, a molecular beam epitaxy process may be used to co-deposit transition metals and chalcogen elements on the substrate, thereby growing a thin film with minimal impurities.

At this time, the elemental ratio of the co-deposited transition metals and chalcogen elements is a key factor determining the chemical composition of the thin film, and the substrate temperature provides thermodynamic energy for surface diffusion and self-insertion of atoms, thereby inducing high-quality thin film growth.

At this time, if the substrate temperature is lower than the aforementioned temperature range, a thin film with an insufficient amount of self-inserted M atoms may be formed. If the temperature exceeds the aforementioned temperature range, a thin film with an excessive amount of self-inserted M atoms may be formed. Therefore, it is desirable to meet the aforementioned temperature range.

Meanwhile, after the manufacturing of the two-dimensional ferromagnetic thin film, a post-heat treatment at a temperature ranging from 200° C. to 360° C. may be further included to improve the crystallinity of the two-dimensional ferromagnetic thin film and remove internal defects.

If the post-heat treatment temperature is below 200° C., the problem of M_{1+δ}X₂ having a homogeneous chemical composition not being formed within the substrate space may arise. If the temperature exceeds 360° C., the crystal structure may be formed as M_{1+δ}X₂ with spatial inversion symmetry, or the X atoms may be vaporized by heat, significantly changing the chemical composition. Therefore, a post-heat treatment at a temperature ranging from 200° C. to 360° C. may be preferable.

This process allows the self-inserted atoms to occupy stable positions within the crystal lattice, thereby enhancing the stability of the spin structure.

Hereinafter, the present invention will be described in more detail through examples and experimental examples. These examples and experimental examples are only for illustrating the present invention, and the scope of the present invention is not limited by these examples and experimental examples.

### Example: Cr_{1+δ}Te₂ Manufacturing

First, Cr was prepared as the transition metal and Te as the chalcogen element.

Furthermore, a sapphire substrate was prepared and cleaned with acetone and isopropyl alcohol solutions.

Then, the chemically cleaned sapphire substrate was loaded into the molecular beam epitaxy (MBE) growth equipment.

The MBE equipment was maintained at an ultra-high vacuum of 3×10⁻⁹ or lower.

Furthermore, to remove any impurities that may exist on the sapphire substrate surface, the substrate was pre-heated at 300° C. and 600° C. for approximately one hour.

Afterwards, Cr and Te were vaporized and deposited onto the substrate using a thermal effusion cell containing Cr and Te within the MBE growth equipment at an appropriate temperature.

For the Cr-ejection cell, temperatures of approximately 1280° C. to 1300° C. were applied, and for the Te-ejection cell, temperatures of approximately 230° C. to 250° C. were applied. The amount of atoms sprayed onto the substrate was controlled to achieve a Cr:Te ratio of approximately 1:2.71 to 1:6, depending on the composition, to achieve specific compositions.

Furthermore, the substrate temperature during growth was controlled from 200° C. to 360° C. to achieve specific compositions, and the post-annealing temperature was adjusted to optimize crystallinity for each composition.

The post-annealing temperature was controlled from 200° C. to 360° C., depending on the composition.

Thus, a two-dimensional ferromagnetic thin film, Cr_{1+δ}Te₂, was fabricated.

### Experimental Example 1: Varied Compositions and Crystal Structures of Cr_{1+δ}Te₂ by Controlling the Amount of Cr Self-Intercalation

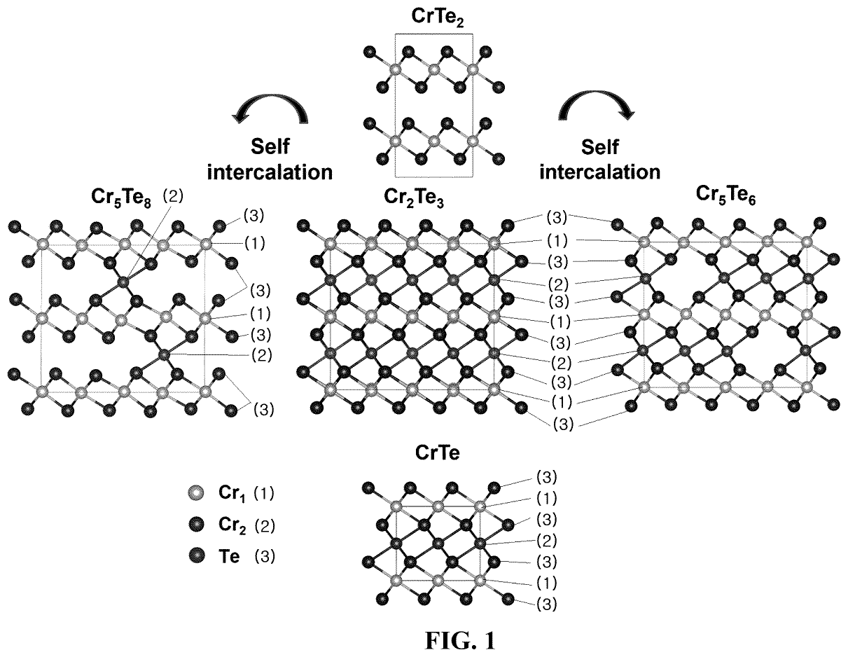

FIG. 1 shows the composition and crystal structure of Cr_{1+δ}Te₂ depending on the amount of Cr self-intercalation.

Referring to FIG. 1, Cr_{1+δ}Te₂ can exhibit diverse compositions and crystal structures depending on the amount of Cr self-intercalation, demonstrating that its magnetic properties can vary significantly.

Changes in the amount of self-intercalation directly affect the crystal symmetry of the material. If the symmetry of the magnetic film is broken, an environment is created where the Djalosinski-Moriya interaction (DMI) may occur.

In the case of Cr_{1+δ}Te₂, as the value of δ increases from 0, the symmetric trigonal structure transitions to an asymmetric trigonal structure. When δ reaches ⅓, the structure becomes symmetric trigonal.

At this time, if δ is increased further to more than ½, it will have an asymmetric crystal structure again, and if it is increased further, it will have various crystal structures, and when δ becomes 1, it will change into a three-dimensional ferromagnetic material.

At this point, if δ is further increased to more than ½, the asymmetric crystal structure reappears.

Experimentally, as shown in the examples, molecular beam epitaxy was used to grow Cr_{1+δ}Te₂, and the growth and post-annealing temperatures were carefully adjusted to achieve Cr_{1+δ}Te₂ with specific compositions.

The variation in δ was achieved by varying the ratio of Cr:Te atoms ejected during growth from 1:2.71 to 1:6.03. Various heat treatment conditions were applied to determine the optimal crystallinity for each composition.

Through this process, we confirmed that growth can be achieved by varying the amount of self-insertion of Cr atoms, and the resulting crystal symmetry and magnetic properties were measured.

### Experimental Example 2. Analysis of Real-Space Berry Curvature

### Experimental Example 2-1. Method for Generating Real-Space Berry Curvature

Real-space Berry curvature may be generated by asymmetric spins, or chiral spin structures, within magnetic materials.

The physical factors that form real-space Berry curvature, or chiral spin structures, require the presence of DMI in addition to exchange interactions in the magnetic Hamiltonian.

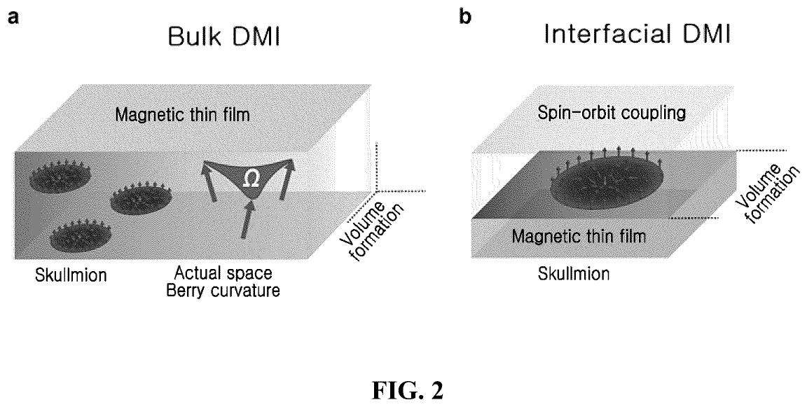

FIG. 2 is a schematic view of (a) the bulk DMI and (b) the interface DMI, which are physical factors that generate real-space Berry curvature.

Referring to FIG. 2, DMI requires strong spin-orbit coupling and a break in inversion symmetry to occur. Depending on the spatial distribution of the break in inversion symmetry, DMI can be divided into bulk DMI (FIG. 2A) and interfacial DMI (FIG. 2B).

Bulk DMI occurs when inversion symmetry is broken in volume space, allowing real-space Berry curvature to form in a three-dimensional volume. Interfacial DMI occurs when inversion symmetry is broken in surface space, allowing real-space Berry curvature to form in a two-dimensional area.

In Cr_{1+δ}Te₂, the formation of bulk DMI can be achieved by controlling crystal symmetry through Cr atom self-insertion, thereby inducing real-space Berry curvature.

### Experimental Example 2-2. Method for Measuring the Phase Hall Effect Proportional to the Real-Space Berry Curvature and Separating the Signals

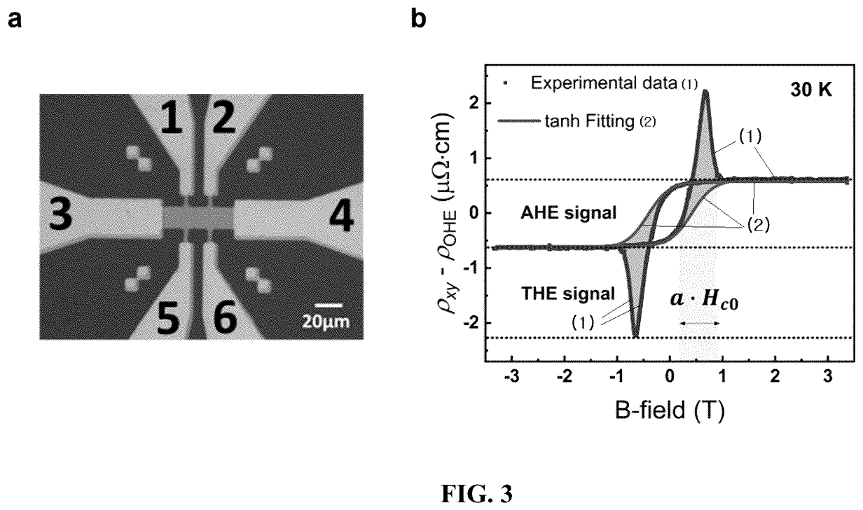

FIG. 3 shows a method for measuring the phase Hall effect, which is proportional to real-space Berry curvature, wherein (a) an optical image of a standard Hall bar element for measuring the phase Hall effect, and (b) a graph for separating the phase Hall effect contribution from the Hall effect of a magnetic thin film.

Referring to FIG. 3, the phase Hall effect is an electrical signal proportional to the real-space Berry curvature, and a standard Hall bar element as shown in FIG. 3A was fabricated to measure it.

When the Hall effect is measured after growing a magnetic thin film, the Hall resistivity is generally expressed as the sum of the normal Hall effect and the abnormal Hall effect, as shown in Equation (1) below.

In equation (1), ρ_{xy}(H) is the Hall resistivity depending on the magnetic field, R₀ is the normal Hall effect coefficient, R_{S} is the abnormal Hall effect coefficient, and M is the magnetization.

$${ρ}_{x y} ( H ) = {R}_{0} H + {R}_{S} M \qquad ( 1 )$$

However, if a chiral spin structure exists, a phase Hall effect resistivity term is generated according to the phase Hall effect, and in that case, when the Hall effect is measured, it appears as shown in Equation (2) below.

In the case of equation (2), P is the spin polarization of the magnetic material, Ωᵣ is the spin polarization of the magnetic material, and this real-space Berry curvature acts as a virtual magnetic field in electronic conduction.

$${ρ}_{x y} ( H ) = {R}_{0} H + {R}_{S} M + P {R}_{0} {Ω}_{r} \qquad ( 2 )$$

Experimentally, the crystal symmetry was controlled stepwise by varying the δ value of Cr_{1+δ}Te₂ from 0.25 to 0.6.

Hall effect measurements were performed at low temperatures and under applied magnetic fields. An analytical technique was used to separate the anomalous Hall effect and the phase Hall effect in Cr_{1+δ}Te₂.

The analytical technique is as follows:

First, Hall resistivity data were measured at varying temperatures and magnetic fields in several Tesla numbers or Tesla units for each temperature. The linear term due to the normal Hall effect was subtracted, and the anomalous Hall effect contribution was fitted using the tanh function.

The fitted anomalous Hall effect was then subtracted from the total signal to derive the pure phase Hall effect contribution. This allows for the calculation of the phase Hall effect amplitude, which is proportional to the real-space Berry curvature for each δ.

To accurately derive the phase Hall effect contribution, the fitting parameters were constrained so that the coercivity lies within the magnetic field where the phase Hall effect signal appears.

This method takes into account the chiral spin structure that occurs during the magnetization switching process, making it crucial for accurately isolating the anomalous Hall effect contribution and, therefore, for accurately estimating the phase-dependent Hall effect contribution.

Therefore, the method may accurately measure real-space Berry curvature in ferromagnetic materials such as Cr_{1+δ}Te₂, providing fundamental data and methodology for its utilization.

### Experimental Example 3. Phase Hall Effect Depending on the Amount of Cr Atom Self-Insertion in Cr_{1+δ}Te₂

### Experimental Example 3-1. Phase Hall Effect and Magnetic Properties of Cr_{1.6}Te₂

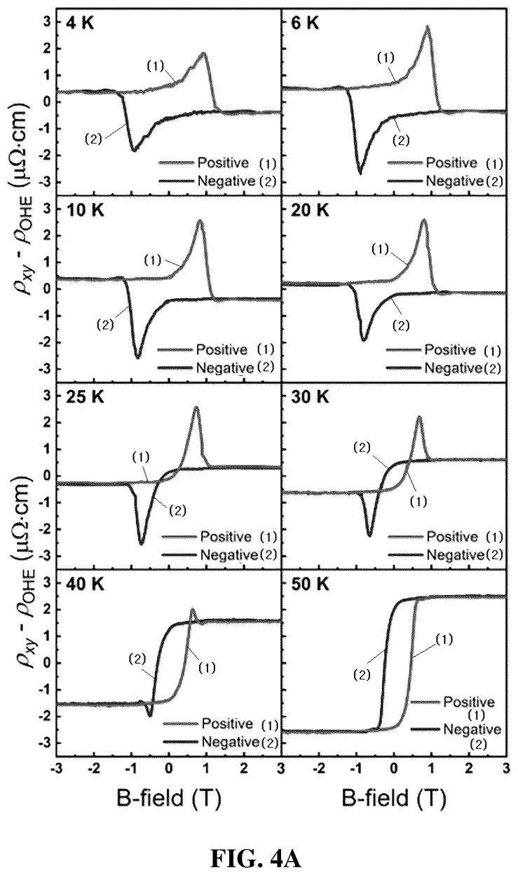

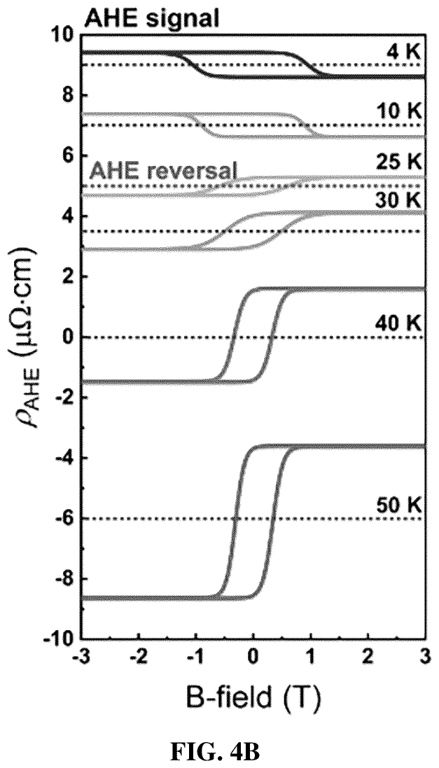

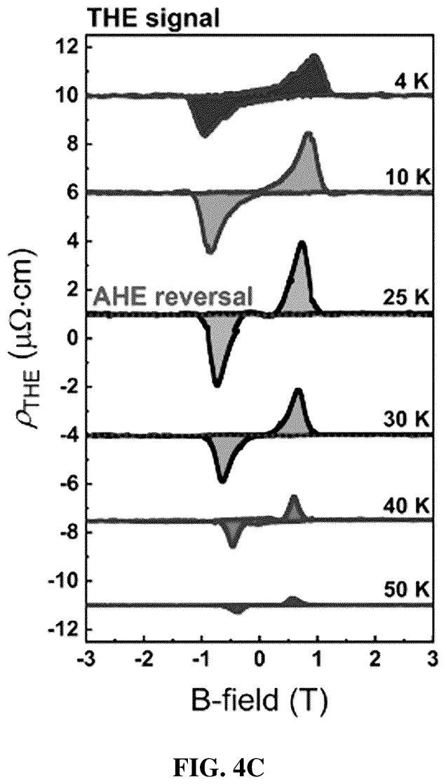

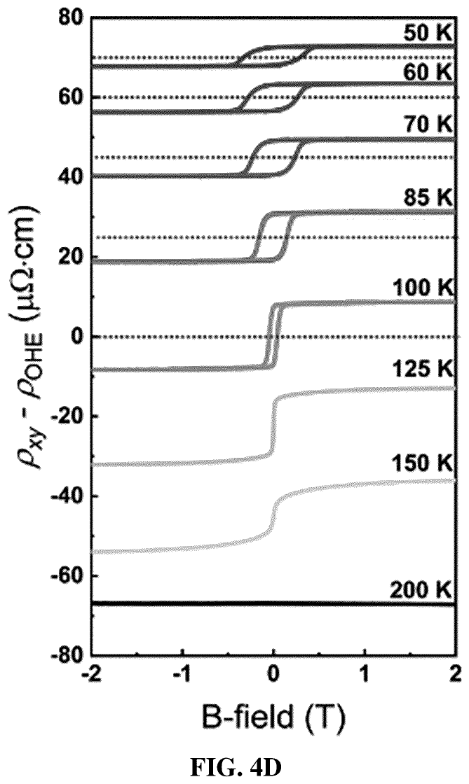

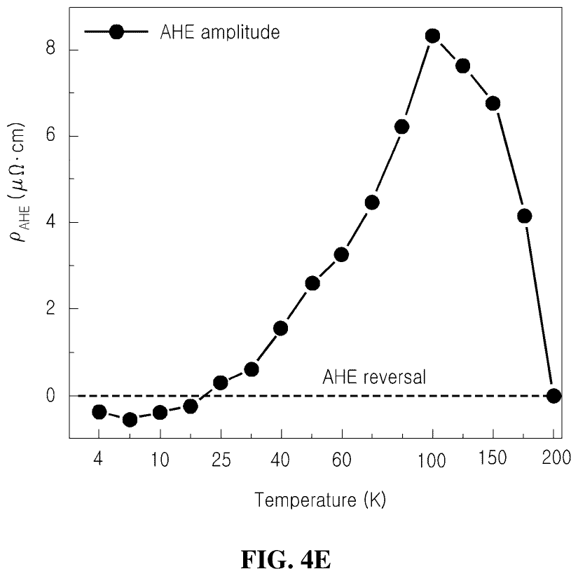

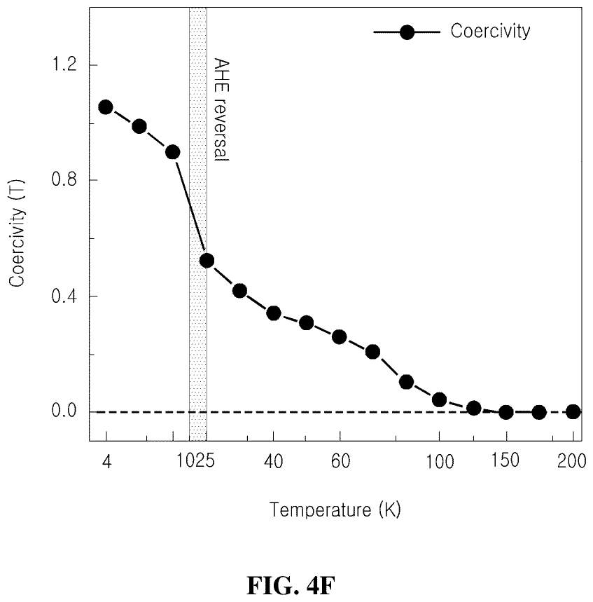

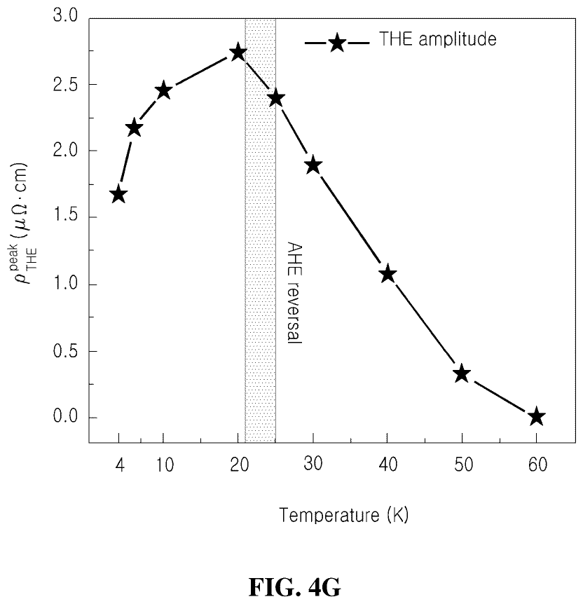

FIG. 4 shows the results of Hall effect measurements of Cr_{1.6}Te₂, including (a) temperature-dependent Hall resistivity vs. magnetic field graphs (below 50 K), (b) temperature-dependent anomalous Hall effect extracted from the graph in (a), (c) temperature-dependent phase Hall effect extracted from (a), (d) temperature-dependent Hall resistivity vs. magnetic field graphs (above 50 K), (e) temperature-dependent anomalous Hall effect amplitude extracted from (b) and (d), (f) temperature-dependent coercivity extracted from (b) and (d), and (g) temperature-dependent phase Hall effect amplitude extracted from (a).

To determine whether the phase Hall effect, which is proportional to the real-space Berry curvature, may be observed in a magnetic thin film, as shown in FIG. 4, the Hall resistivity was measured as a function of magnetic field for Cr_{1.6}Te₂ at δ=0.6, and the anomalous Hall effect and the phase Hall effect were separated.

FIG. 4A clearly shows a camel-back-shaped signal, characteristic of the phase Hall effect, indicating that Cr_{1.6}Te₂ exhibits a broken crystal inversion symmetry.

In other words, the magnetic structure at this composition exhibits a strong spin asymmetric arrangement, which is closely related to the real-space Berry curvature generated by the bulk DMI resulting from the self-insertion of Cr atoms.

Furthermore, the phase Hall effect was confirmed to be present up to 50 K. The anomalous Hall effect and the phase Hall effect signals were separated using the method described in Experimental Example 2-2, as shown in FIGS. 4A, 4B, and 4C.

As shown in FIG. 4D, the Hall resistivity effect was measured as a function of magnetic field above 50 K. FIGS. 4E and 4F show the temperature-dependent phase Hall effect amplitude and coercivity for the entire temperature range.

The most important indicator for assessing the potential for use in high-performance spintronic devices is the temperature-dependent phase Hall effect amplitude, as shown in FIG. 4G. Cr_{1.6}Te₂ exhibits a very large phase Hall effect amplitude, suggesting its potential as a key material for next-generation memory devices.

### Experimental Example 3-2. Phase Hall Effect and Magnetic Properties of Cr_{1.5}Te₂, Cr_{1.35}Te₂, Cr_{1.25}Te₂

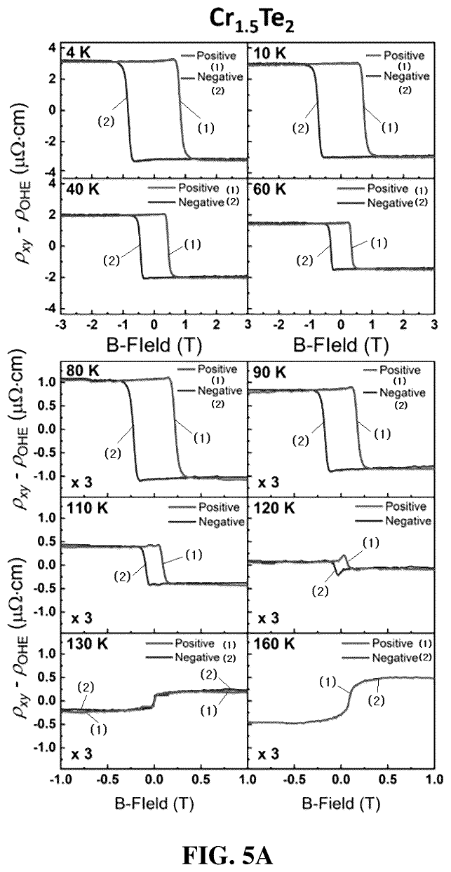

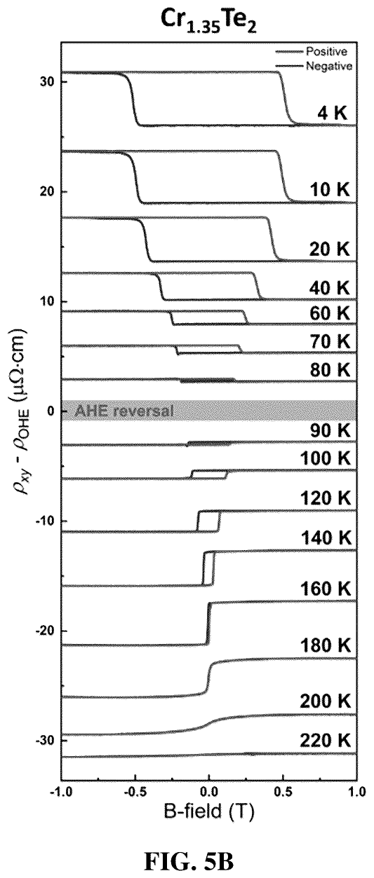

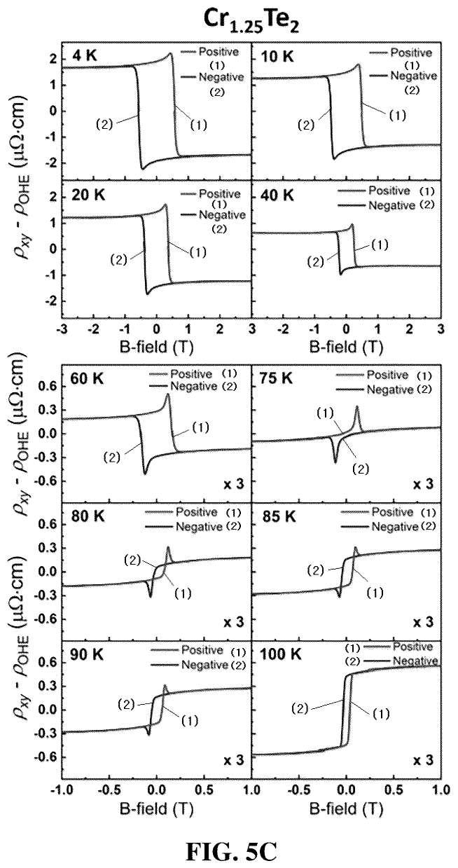

FIG. 5 shows temperature-dependent Hall resistivity vs. magnetic field graphs of (a) Cr_{1.5}Te₂, (b) Cr_{1.35}Te₂, and (c) Cr_{1.25}Te₂.

To determine how the crystal symmetry and real-space Berry curvature change with the amount of Cr self-insertion in Cr_{1+δ}Te₂, the Hall resistivity of Cr_{1+δ}Te₂ was measured as a function of magnetic field while decreasing δ, as shown in FIG. 5.

The results show that the phase Hall effect and magnetic properties of Cr_{1+δ}Te₂ are nonlinearly controlled as δ gradually decreases, suggesting that crystal symmetry and real-space Berry curvature can be controlled by Cr self-insertion.

For Cr_{1.5}Te₂, where δ equals 0.5, a very small phase Hall effect is observed compared to Cr_{1.6}Te₂. This provides evidence that the real-space Berry curvature can be significantly controlled by carefully adjusting the amount of Cr self-insertion.

However, the 120K data in FIG. 5A confirms that the phase Hall effect is weak, suggesting that Cr_{1.5}Te₂ exhibits a broken inversion symmetry.

On the other hand, for Cr_{1.35}Te₂ at δ=0.35, as shown in FIG. 5B, the phase Hall effect was not observed at all measurement temperatures. This suggests a crystal structure with inversion symmetry, suggesting the absence of a chiral spin structure and the disappearance of the real-space Berry curvature present at δ<0.35.

When δ was further reduced and the Hall resistivity of Cr_{1.25}Te₂ at δ=0.25 was measured, a significant phase Hall effect was observed again, as shown in FIG. 5C.

In other words, by adjusting the amount of Cr self-insertion, the phase Hall effect was significantly altered. This confirms the effective control of the real-space Berry curvature and indirectly provides an indication of the bulk DMI intensity dependent on crystal symmetry.

Comparative analysis of the phase Hall effect amplitude by measuring the Hall resistivity effect according to the amount of Cr self-insertion can not only help understand the influence on the magnetic and crystallographic properties of materials, but also play a major role in suggesting important spintronic indicators for industrial applications.

### Experimental Example 4. Control of Real-Space Berry Curvature, Crystal Symmetry, and Bulk DMI Intensity in Cr_{1+δ}Te₂ Through Cr Atom Self-Insertion

In conclusion, Cr atom self-insertion is a key variable that allows for precise control of the crystal symmetry, bulk DMI intensity, and real-space Berry curvature in Cr_{1+δ}Te₂.

When the δ value ranges from 0.25 to 0.6, the crystal structure transitions between asymmetric trigonal and symmetric trigonal structures, which can be attributed to the control of the bulk DMI.

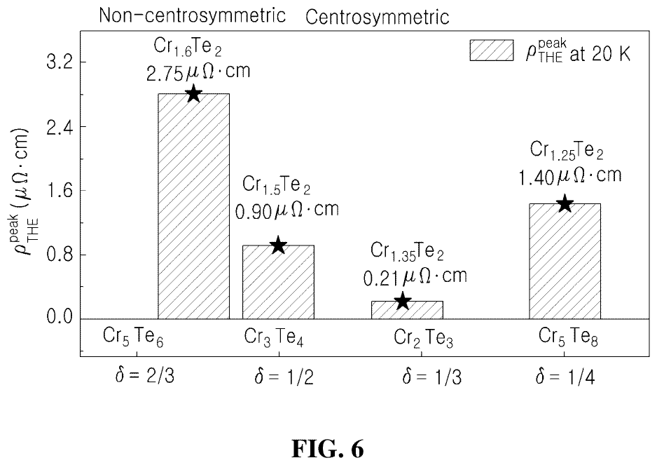

FIG. 6 is a graph that summarizes the phase Hall effect amplitude at 20 K according to the amount of Cr atomic self-insertion, and is a graph that expresses the crystal symmetry for each composition.

If we organize the crystal symmetry information and phase Hall effect amplitude according to δ, as shown in FIG. 6, it is possible to confirm that when δ=0.6, crystal symmetry is broken and the phase Hall effect amplitude is the largest, indicating the largest real-space Berry curvature and bulk DMI intensity. Reducing δ to 0.5 sharply reduces the phase Hall effect amplitude. When δ=0.35, crystal symmetry is preserved and the phase Hall effect disappears. Finally, when δ=0.25, crystal symmetry is broken and a fairly large phase Hall effect amplitude appears.

These experimental results provide important design principles for precisely controlling and optimizing the real-space Berry curvature according to crystal symmetry and bulk DMI intensity of Cr_{1+δ}Te₂, and can be used to implement spintronic devices based on this principle.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. A two-dimensional ferromagnetic thin film with the formula M_{1+δ}X₂ (M is a transition metal, X is a chalcogen element, 0<δ<1),
wherein the two-dimensional ferromagnetic thin film comprises a structure in which MX₂ atomic layers are stacked, and
a real-space Berry curvature is formed inside the two-dimensional ferromagnetic thin film by inserting M atoms between the MX₂ atomic layers to control the δ value of M_{1+δ}X₂.

2. The two-dimensional ferromagnetic thin film of claim 1,
wherein the X is tellurium (Te) or selenium (Se), and
the M is chromium (Cr), manganese (Mn), vanadium (V), or iron (Fe).

3. The two-dimensional ferromagnetic thin film of claim 2,
wherein the M is chromium (Cr),
the X is tellurium (Te), and
the two-dimensional ferromagnetic thin film is Cr_{1+δ}Te₂ (0<δ<1).

4. The two-dimensional ferromagnetic thin film of claim 1,
wherein the value δ, which is the amount of the self-inserted M atoms, is 0.25≤δ≤0.6.

5. The two-dimensional ferromagnetic thin film of claim 4,
wherein the value δ, which is the amount of the self-inserted M atoms, is 0.25≤δ≤0.35 or 0.5<δ≤0.6.

6. The two-dimensional ferromagnetic thin film of claim 1,
wherein the two-dimensional ferromagnetic thin film comprises a skyrmion, which is a chiral spin structure formed inside the thin film with the real-space Berry curvature.

7. A method for manufacturing a two-dimensional ferromagnetic thin film of claim 1, the method comprising:
preparing a substrate; and
co-depositing a transition metal and a chalcogen element on the substrate to form an MX₂ atomic layer, and self-inserting the transition metal between the MX₂ atomic layers to manufacture a two-dimensional ferromagnetic thin film represented by the chemical formula M_{1+δ}X₂ (M is a transition metal, X is a chalcogen element, 0<δ<1).

8. The two-dimensional ferromagnetic thin film of claim 7,
wherein the transition metal is chromium (Cr), and
the chalcogen element (X) is tellurium (Te).

9. The two-dimensional ferromagnetic thin film of claim 7,
wherein the value δ, which is the amount of the self-inserted M atoms, is 0.25≤δ≤0.35 or 0.5<δ≤0.6.

10. The two-dimensional ferromagnetic thin film of claim 7,
wherein in the manufacturing of the two-dimensional ferromagnetic thin film,
the element ratio of the transition metal and chalcogen elements co-deposited on the substrate is 1:2.71 to 1:6.03, and
the temperature of the substrate is maintained in the range of 200° C. to 360° C. to control the δ value, which is the amount of self-inserted M atoms.

11. The two-dimensional ferromagnetic thin film of claim 7,
further comprising, after the manufacturing of the two-dimensional ferromagnetic thin film,
performing post-heat treatment at a temperature in the range of 200° C. to 360° C. to improve the crystallinity of the two-dimensional ferromagnetic thin film.

12. A racetrack memory comprising a two-dimensional ferromagnetic thin film of claim 1.
